(19) United States
(12) Patent Application Publication
(10) Pub. No.: US 2025/0311380 A1
(43) Pub. Date: Oct. 2, 2025

(54) SIDEWALL DOPING FOR RESISTANCE REDUCTION OF GAA-LIKE DEVICES

(71) Applicant: Applied Materials, Inc., Santa Clara, CA (US)

(72) Inventors: Yan ZHANG, Westford, MA (US); Nicolas Louis BREIL, San Jose, CA (US); San-Kuei LIN, Los Gatos, CA (US); Naushad K. VARIAM, Marblehead, MA (US)

(73) Assignee: Applied Materials, Inc., Santa Clara, CA (US)

(21) Appl. No.: 18/623,624

(22) Filed: Apr. 1, 2024

(51) Int. Cl. H01L 21/8238; H01J 37/317; H01L 21/265; H01L 21/324; H01L 29/66

(52) U.S. Cl. CPC H10D 84/017; H01J 37/3171; H01L 21/26513; H01L 21/324; H10D 30/014; H10D 84/038; H01J 2237/338

(57) ABSTRACT

Approaches herein relate to gate-all-around based devices and complementary field effect transistor devices. One method may include forming a plurality of layered stacks atop a base layer, wherein a first layered stack and a second layered stack of the plurality of layered stacks each comprises a plurality of alternating first layers and second layers, and wherein the first and second layered stacks define a trench. The method may further include forming a source/drain (S/D) epitaxial layer along a sidewall of the first layered stack and the second layered stack, and performing an implant by directing ions to the S/D epitaxial layer, wherein the implant increases an ion concentration along an outer surface of the S/D epitaxial layer. The method may further include performing a thermal process on the plurality of layered stacks and the S/D epitaxial layer after performing the implant.

### FIELD OF THE DISCLOSURE

The present embodiments relate to semiconductor device patterning, and more particularly, to devices and methods for resistance reduction of metal sidewall contacts using a sidewall doping implant.

### BACKGROUND OF THE DISCLOSURE

As integrated circuit (IC) technologies progress towards smaller technology nodes, multigate devices have been used to improve gate control by increasing gate-channel coupling, reducing off-state current, and reducing short-channel effects. A multigate device generally refers to a device having a gate structure, or portion thereof, disposed over more than one side of a channel region. Field effect transistors (FETs) and gate-all-around (GAA) transistors, both also referred to as non-planar transistors, are examples of multigate devices that provide high performance and low leakage applications. The channel region of GAA transistors may be formed from nanowires, nanosheets (NS), or other nanostructures.

GAA and complementary FET device performance is highly dependent upon the number of stacked NS. With conventional S/D contact schemes, a greater number of stacked NS increases the effects from S/D resistance, thus decreasing ring oscillator speed. Wrap-around-contacts (WAC) can help reduce resistance with an enlarged contact area after trimming S/D epi. However, this benefit is NS-width dependent. Especially for narrow NS-width devices for which the resistance effects from side of S/D epi still exist, device performance becomes limited.

More recent S/D contact schemes for metal sidewall (MSW) contacts can enlarge the contact area and reduce resistance effects that enable larger stacked NS for device performance improvement. However, resistance levels are inadequate because of low doping along S/D epi/metal sidewall interface. Since MSW is closer to the channel region, conventional contact ion implants may degrade short-channel effects. In addition, the large aspect ratio (AR) from the increased number of NS and stacked devices like CFET makes it difficult for conventional ion implants to achieve conformal doping along epi sidewalls due to shadowing effect. On the other hand, for continuous scaling, backside power distributed network (BSPDN) will be adopted, and contacts need to be formed from backside (BSCON). The formation of a low contact resistance from backside is quite challengeable due to the low temperature limitation.

Accordingly, improved approaches are needed to form frontside contact or backside contact for GAA-type of devices.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a method may include forming a plurality of layered stacks atop a base layer, wherein a first layered stack and a second layered stack of the plurality of layered stacks each comprises a plurality of alternating first layers and second layers, and wherein the first layered stack and the second layered stack of the plurality of layered stacks define a trench. The method may further include forming a source/drain epitaxial layer along a sidewall of the first layered stack and the second layered stack, and performing an implant by directing ions to the source/drain epitaxial layer, wherein the implant increases an ion concentration along an outer surface of the source/drain epitaxial layer. The method may further include performing a thermal process on the plurality of layered stacks and the source/drain epitaxial layer after performing the implant.

In another aspect, a method for forming a gate-all-around (GAA) device may include forming a plurality of nanosheet (NS) stacks atop a substrate, wherein a first NS stack and a second NS stack of the plurality of NS stacks each comprises a plurality of alternating first layers and second layers, and wherein the first NS stack and the second NS stack of the plurality of layered stacks define a trench extending to an upper surface of the substrate. The method may further include forming a source/drain epitaxial layer along a sidewall of the first NS stack and the second NS stack, and performing an implant by directing ions to the source/drain epitaxial layer, wherein the implant increases an ion concentration along an outer surface of the source/drain epitaxial layer. The method may further include performing a thermal process on the plurality of NS stacks and the source/drain epitaxial layer after performing the implant.

In yet another aspect, an ion processing tool may be operable to direct ions to a source/drain epitaxial layer formed along a sidewall of a first nanosheet stack and a second nanosheet stack of a plurality of nanosheet stacks, wherein the implant increases an ion concentration at an intersection of an outer surface of the source/drain epitaxial layer and a metal sidewall contact, and wherein each of the first and second nanosheet stacks comprises a plurality of alternating first layers and second layers formed atop a base layer.

### BRIEF DESCRIPTION OF THE DRAWINGS

The accompanying drawings illustrate exemplary approaches of the disclosure, including the practical application of the principles thereof, as follows:

FIGS. 1A-1C are cross-sectional views of a process for forming a GAA device structure according to embodiments of the present disclosure;

FIGS. 2A-2C are cross-sectional views of a process for forming another GAA device structure according to embodiments of the present disclosure;

FIGS. 3A-3C are cross-sectional views of a process for forming a CFET device structure according to embodiments of the present disclosure;

FIGS. 4A-4C are cross-sectional views of a process for forming another CFET device structure according to embodiments of the present disclosure;

FIG. 5 illustrates a perspective view of an exemplary plasma doping system, according to embodiments of the present disclosure; and

FIG. 6 illustrates a perspective view of an example processing system, according to embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods, systems, and devices in accordance with the present disclosure will now be described more fully hereinafter with reference to the accompanying drawings, where various embodiments are shown. The methods, systems, and devices may be embodied in many different forms and are not to be construed as being limited to the embodiments set forth herein. Instead, these embodiments are provided so the disclosure will be thorough and complete, and will fully convey the scope of the methods to those skilled in the art.

With the adoption of backside power distributed networks (BSPDN) for advanced NS and CFETs, backside contacts (BSCON) are required for continuous cell height scaling. However, as compared to frontside contact (FSCON) schemes, contact resistance (Rc) reduction for BSCON is quite challenging due to the limited thermal budget. Additionally, the number of NS is still limited due to resistance issues for BSCON.

As will be described further herein, implementing a new contact scheme MSW for advanced NS and CFET technologies with BSPDN will improve BSCON formation. Embodiments of the present disclosure provide sidewall doping at room-temperature (RT), or higher, to reduce Rc in MSW contact for both FSCON and BSCON. At least the following advantages are provided by the solutions of the present disclosure. First, conformally doped S/D epi sidewalls have almost no limitation on AR or number of NS. Second, less doping induced defects with plasma doping (PLAD) process, and thus less SCEs degradation is achieved. Third, subsequent thermal processing (e.g., annealing) steps from frontside process can activate dopants and thus reduce Rc. Fourth, this MSW contact scheme with sidewall doping done from the device frontside is suitable for both FSCON and BSCON. This is especially beneficial for BSCON for which the Rc reduction is quite challenging due to temperature limitations.

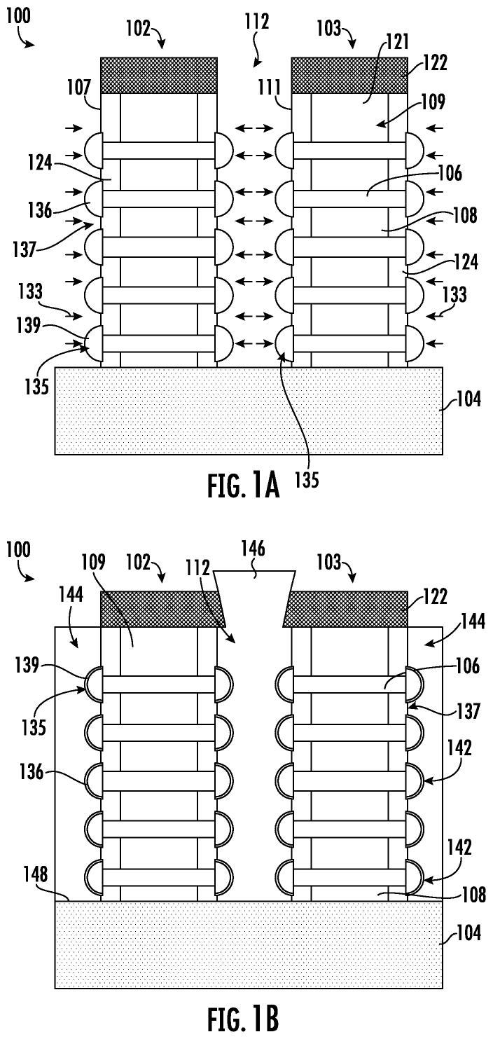

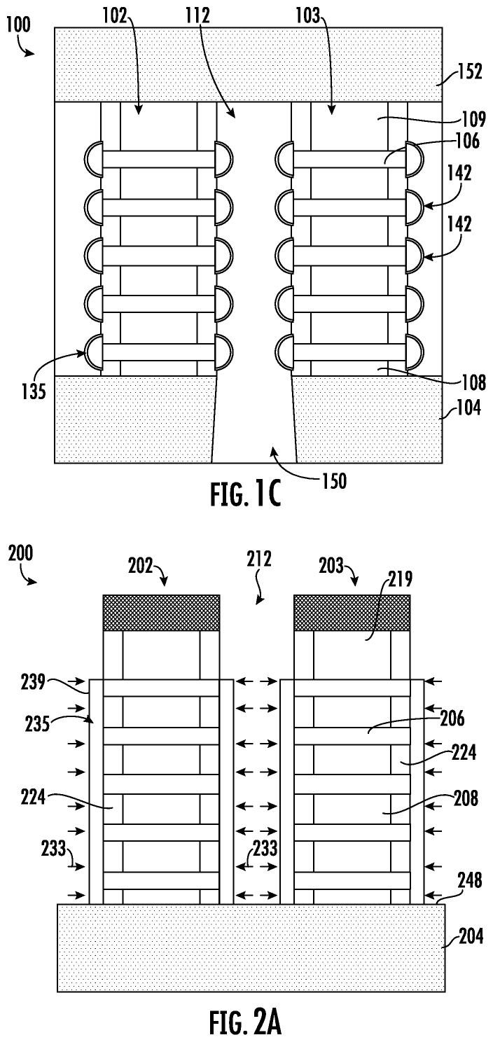

With reference to FIG. 1A, an approach for forming a semiconductor device (hereinafter “device”) 100 according to one or more embodiments will be described. The device 100 may be a GAA device structure, a vertical GAA device structure, a horizontal GAA device structure, or a fin-like field effect transistor (FinFET) device structure. In some embodiments, the device 100 may be a stacked nanosheet complementary field effect transistor (CFET) device having a GAA structure. As shown, the device 100 may include a first stack 102 and a second stack 103 (sometimes referred to herein as nanosheet stacks) including a plurality of alternating first layers 106 and second layers 108 formed over a base layer 104.

The term ‘nanosheet,’ as used herein, refers to a sheet or a layer having nanoscale dimensions. Further, the term ‘nanosheet’ is meant to encompass other nanoscale structures such as nanowires. For instance, ‘nanosheet’ can refer to a nanowire with a larger width, and/or ‘nanowire’ can refer to a nanosheet with a smaller width, and vice versa.

In various embodiments, the plurality of alternating first layers 106 and second layers 108 may include between two (2) and ten (10) first layers 106 and between two (2) and ten (10) second layers 108. A composition of the first layers 106 may be different than a composition of the second layers 108 to achieve etching selectivity and/or different oxidation rates during subsequent processing, for example. In some embodiments, the plurality of alternating first layers 106 and second layers 108 may include different materials, different constituent atomic percentages, different constituent weight percentages, and/or other different characteristics to achieve desired etching selectivity.

In the present embodiment, the first layers 106 may include silicon (Si) and the second layers 108 may include silicon germanium (SiGe), which has a different etch selectivity than silicon. Although non-limiting, a thickness of each first layer 106 may be about 1 nm to about 10 nm, a thickness of each second layer 108 may be about 1 nm to about 10 nm, and the two thicknesses can be the same or different. Although non-limiting, the plurality of alternating first layers 106 and second layers 108 may be epitaxially grown in the depicted interleaving and alternating configuration, layer-by-layer, until a desired number of semiconductor layers is reached.

The first and second layers 106, 108 may be processed (e.g., etched) to form a plurality of structures, or nanosheets (e.g., stacks 102, 103) extending in a vertical direction from the base layer 104. Each of the stacks 102, 103 may include a set of opposing sidewall surfaces 107, 111. The stacks 102, 103 may be separated by a trench 112. The stacks 102, 103 may be patterned by any suitable method. For example, the nanosheets may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. Embodiments herein are not limited in this context.

According to an exemplary embodiment, the base layer 104 may be a bulk semiconductor substrate. As used herein, the term “bulk semiconductor substrate” refers to a substrate in which the entirety of the substrate is comprised of a semiconductor material. The bulk semiconductor substrate may comprise any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In some embodiments, the semiconductor material is silicon (Si). In one or more embodiments, the base layer 104 may include a semiconductor material, e.g., silicon (Si), carbon (C), germanium (Ge), silicon germanium (SiGe), germanium tin (GeSn), other semiconductor materials, or any combination thereof. In one or more embodiments, the base layer 104 may include one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In some embodiments, the semiconductor material may be a doped material, such as n-doped silicon (n-Si), or p-doped silicon (p-Si). In some embodiments, the substrate may be doped using any suitable process such as an ion implantation process. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers. In one or more embodiments, the dopant is selected from one or more of boron (B), gallium (Ga), phosphorus (P), arsenic (As), other semiconductor dopants, or combinations thereof.

A gate structure 109 (e.g., dummy gate) may also be formed over the stacks 102, 103, a portion of which is shown. The dummy gate structure 109 may include a sacrificial gate having a gate material layer 121 and an interlayer dielectric (ILD) 122 formed atop the gate material layer 121. In some embodiments, the gate material layer 121 may be an amorphous silicon (a-Si) or a polysilicon.

A lateral selective dry etch may be performed to trim the second layers 108 slightly (e.g., a few nm) to form gaps between Si nanosheets. One or more low-k materials may then be used to fill these gaps and form an inner spacer 124. In various non-limiting embodiments, low-k materials may include a dielectric having a dielectric constant less than about 7, for example, less than about 5 or even less than about 2.5, such as carbon containing silicon materials such as silicon oxycarbides (SiOC) or silicon carbides, silicon nitrides (SiN) or carbon containing silicon nitride materials (SiCN), and/or boron nitride (BN), silicon boron nitride (SiBN), silicon boron carbide nitride (SiBCN), carbon doped silicon oxide, fluorine doped oxide, porous dielectric, or combinations thereof.

A S/D epitaxial layer 135 may then be formed along the set of opposing sidewall surfaces 107, 111 of the stacks 102, 103. As shown, the S/D epitaxial layer 135 may include a plurality of material formations 136 separated by gaps 137. In some embodiments, an epitaxy process may use chemical vapor deposition (CVD) techniques (e.g., vapor phase epitaxy and/or Ultra-High Vacuum CVD), molecular beam epitaxy, other suitable epitaxial growth processes, or combinations thereof, to form the S/D epitaxial layer 135. The epitaxy process can use gaseous and/or liquid precursors, which interact with the composition of the base layer 104 and the first layers 106 of the stacks 102, 103. As shown, S/D epitaxial layer 135 may be in direct contact with the first layers 106 and with the spacers 124.

In some embodiments, the S/D epitaxial layer 135 may be doped using an in-situ process (i.e., doped during deposition by adding impurities to a source material of the epitaxy process) or an ex-situ process (e.g., doped by an ion implantation process subsequent to a deposition process). For example, one or more implant processes may be performed whereby ions 133 are directed into the stacks 102, 103, including into an exterior surface 139 of the S/D epitaxial layer 135. Although non-limiting, the ions 133 may include p-type or n-type species depending on whether the stacks 102, 103 are nGAA stacks or pGAA stacks, for example. The ions 133 may be further directed into the spacer 124. In some embodiments, the implant is performed at room temperature (e.g., 15-30° C.) or greater.

In this embodiment, the implant process may be a plasma treatment, e.g., plasma doping (PLAD) or decoupled plasma treatment (DPX), which impacts the stacks 102, 103, including the S/D epitaxial layer 135. In various embodiments, the implant process may be delivered at a substantially horizontal angle relative to the stacks 102, 103, as shown, and/or vertically. In the example shown, the ions 133 may simultaneously impact the base layer 104 and the stacks 102, 103, including the spacer 124 and the S/D epitaxial layer 135. Although non-limiting, the implant process may be constant or variable. In some embodiments, a thermal process (e.g., RTA) may be performed after the implant process to activate the dopants, particularly along the exterior surface 139 of the S/D epitaxial layer 135 and along the portions of the spacer 124 left exposed by gaps 137. This area of increased dopant activation is demonstrated as layer 142 in FIG. 1B. As a result of the implantation and thermal processes, Rc may be minimized for the sidewalls of the stacks 102, 103.

In other embodiments, the thermal treatment to activate the dopants may be achieved via one or more subsequent front end of the line (FEOL) thermal processing steps. In yet other embodiments, a first thermal treatment may be performed immediately following the implant process and a second thermal treatment may occur during one or more FEOL processes.

As further shown in FIG. 1B, a metal 144 may then be deposited over stacks 102, 103, including within the trench 112 and along the S/D epitaxial layer 135, to form a frontside contact 146. The metal 144 may extend to an upper surface 148 of the base layer 104, and may extend over layer 142 formed at the exterior surface 139 of the S/D epitaxial layer 135. As a result of the previously performed implant and thermal processes, resistance is lower at the interface between the metal 144 and the S/D epitaxial layer 135. As shown, the frontside contact 146 may extend through an opening of the ILD 122. Although non-limiting, the metal 144 may be, or comprise, cobalt, tungsten, copper, ruthenium, alloys thereof, or a combination thereof, and may be deposited by CVD, ALD, PVD, or another deposition technique.

FIG. 1C demonstrates formation of a backside contact 150 following FEOL, middle end of line (MEOL) and/or back end of line (BEOL) processes. The stacks 102, 103 and the S/D epitaxial layer 135 are formed the same or similar as shown in FIG. 1A and described above. In this embodiment, a dielectric layer 152 may be formed over the gates 109 of the stacks 102, 103. As shown, the dielectric layer 152 may extend across the trench 112 between stacks 102, 103. The metal 144 may be formed over the stacks 102, 103, including within the trench 112. As shown, the backside contact 150 extends through an opening of the base layer 104.

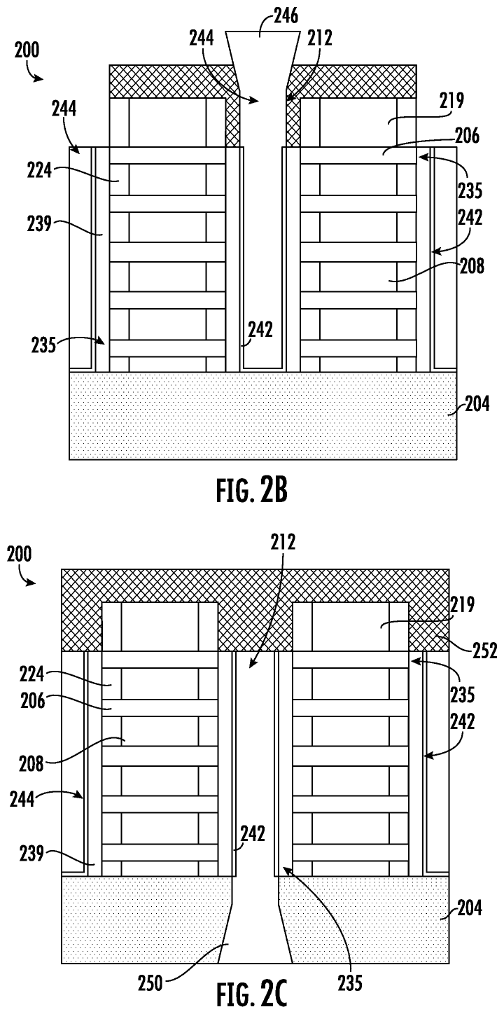

Turning to FIG. 2A, an approach for forming another semiconductor device (hereinafter “device”) 200 according to one or more embodiments will be described. The device 200 may be similar in some aspects to the device 100 described above. As such, only certain aspects of the device 200 will hereinafter be described for the sake of brevity. As shown, the device 200 may include a first stack 202 and a second stack 203 separated by a trench 212, each of the first and second stacks 202, 203 including a plurality of alternating first layers 206 and second layers 208 formed over a base layer 204.

Each of the stacks 202, 203 may include a set of opposing sidewall surfaces 207, 211 upon which a S/D epitaxial layer 235 may be formed. As shown, the S/D epitaxial layer 235 may be a material layer extending continuously from an upper surface 248 of the base layer 204 to a gate 219 of the stacks 202, 203. As shown, S/D epitaxial layer 235 may be in direct contact with the first layers 206 and with spacers 224.

In some embodiments, the S/D epitaxial layer 235 may be doped using one or more implant processes in which ions 233 are directed into the stacks 202, 203, including into an exterior surface 239 of the S/D epitaxial layer 235. Although non-limiting, the ions 233 may include p-type or n-type species depending on whether the stacks 202, 203 are nGAA stacks or pGAA stacks, for example. The ions 233 may be directed into the exposed surfaces of the S/D epitaxial layer 235, and may be performed at room temperature or greater.

In this embodiment, the implant process may be a plasma treatment, e.g., plasma doping (PLAD) or decoupled plasma treatment (DPX), which impacts the stacks 202, 203, including the exterior surface 239 of the S/D epitaxial layer 235. In various embodiments, the doping may be constant or variable, and may be delivered at a substantially horizontal angle relative to the stacks 202, 203, as shown, and/or vertically. In some embodiments, a thermal process (e.g., anneal) may be performed after the implant process to activate the dopants, particularly along the exterior surface 239 of the S/D epitaxial layer 235. This area of increased dopant activation is demonstrated as layer 242 in FIG. 2B. As a result of the implantation and thermal processes, Rc may be minimized for the S/D epitaxial layer 235 of the stacks 202, 203.

In other embodiments, the thermal treatment to activate the dopants may be achieved via one or more subsequent FEOL processing steps. In yet other embodiments, a first thermal treatment may be performed immediately following the implant process and a second thermal treatment may come from one or more FEOL processes.

As further shown in FIG. 2B, a metal 244 may then be deposited over stacks 202, 203, including within the trench 212 and along the S/D epitaxial layer 235, to form a frontside contact 246. The metal 244 may extend to the upper surface 248 of the base layer 104, and may extend over the layer 242 formed at the exterior surface 239 of the S/D epitaxial layer 235. The layer 242 may also be formed on upper surface 248 of the base layer 204. As a result of the previously performed implant and thermal processes, resistance is lower at the interface between the metal 244 and the S/D epitaxial layer 235. As further shown, the frontside contact 246 may extend through an opening of ILD 222.

FIG. 2C demonstrates formation of a backside contact 250. The stacks 202, 203 and the S/D epitaxial layer 235 are formed the same or similar as the process shown in FIG. 2A and described above. In this embodiment, a dielectric layer 252 may be formed over the gates 219 of the stacks 202, 203. As shown, the dielectric layer 252 may extend across the trench 212 between stacks 202, 203. The metal 244 may be formed over the stacks 202, 203, including within the trench 212. As shown, the backside contact 250 extends through an opening of the base layer 204.

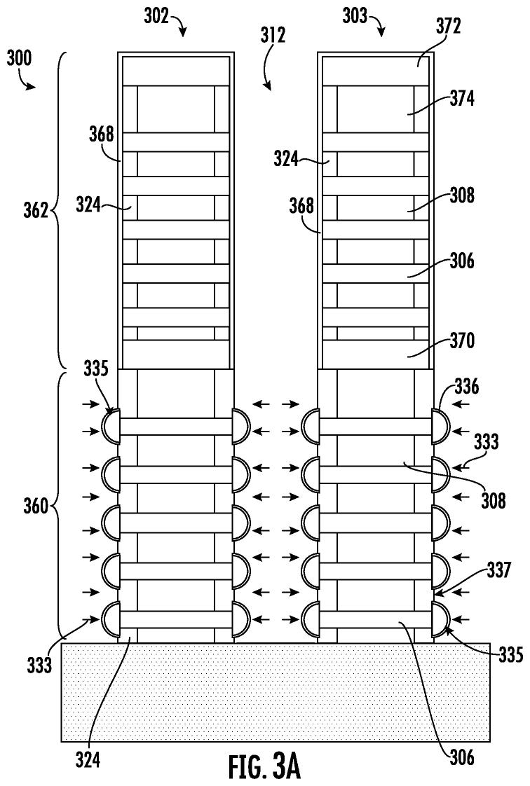

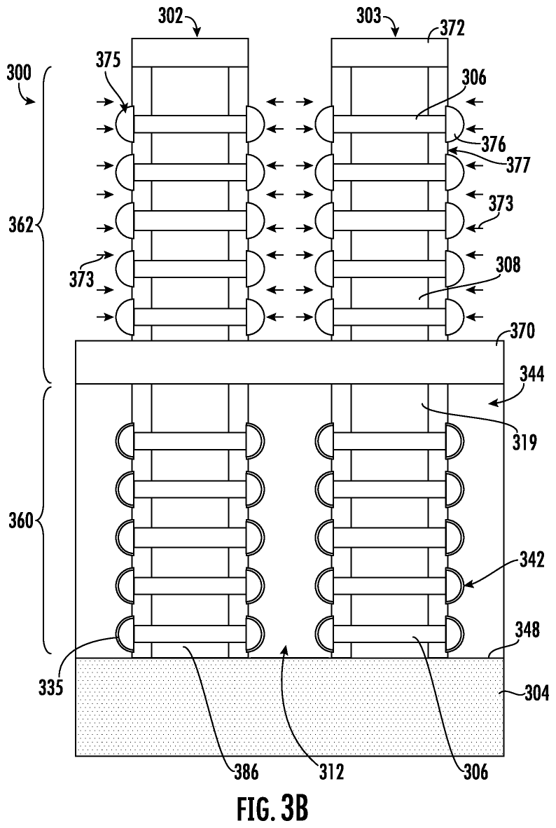

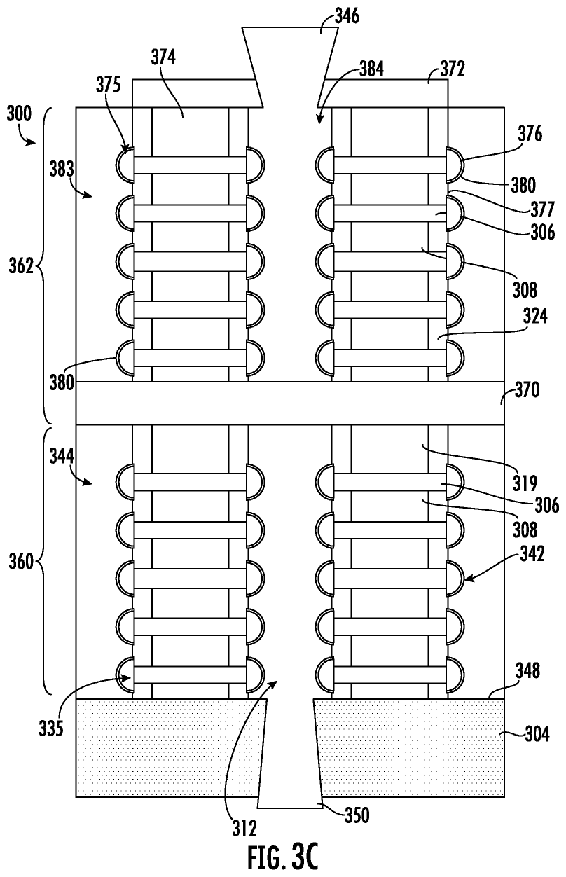

FIG. 3A demonstrates formation of another device 300 according to embodiments of the present disclosure. Device 300 may be a CFET having a pNS beneath an nNS. More specifically, a lower portion 360 of first and second stacks 302, 303 of alternating first layers 306 and second layers 308 may form a device of a first polarity, i.e., a PFET or an NFET, and an upper portion 362 of the first and second stacks 302, 303 of alternating first layers 306 and second layers 308 may form a device of a second/opposite polarity, i.e., an NFET if the lower portion 360 is a PFET, or vice versa. Due to this top-bottom arrangement, a large aspect ratio is present in trench 312, for which a conventional beam-line ion implant is inadequate due to shadowing effect. As such, a PLAD process is beneficial to deliver ions 333 to the sidewalls of the first and second stacks 302, 303. In various embodiments, the PLAD process may provide N and/or P type dopants to an S/D epitaxial layer 335, which is formed along the first layers 306 and a spacer 324. As described above, the S/D epitaxial layer 335 may include a plurality of material formations 336 separated by gaps 337. In some embodiments, a thermal process may be performed after the PLAD process to activate the dopants, as demonstrated by layer 342 in FIG. 3B.

As further shown, the upper portion 362 of the first and second stacks 302, 303 may include a dielectric liner 368 formed over an exterior surface of the first layers 306 and over the spacers 324. The upper portion 362 of the first and second stacks 302, 303 may further include a middle dielectric layer 370 separating the upper portion 362 from the lower portion 360. Each of the first and second stacks 302, 303 of the upper portion 362 may include an interlayer dielectric 372 atop a gate 374. As shown, the dielectric liner 368 is also formed atop the interlayer dielectric 372.

As shown in FIG. 3B, a metal 344 may then be formed over the lower portion 360 of the first stack 302 and over the second stack 303, including within the trench 312 and over the layer 342 of the S/D epitaxial layer 335. In some embodiments, the metal 344 may be formed atop an upper surface 348 of base layer 304.

As further shown, the middle dielectric layer 370 may extend across the trench 312, and the dielectric liner 368 is removed from the stacks 302, 303. Next, another PLAD process may be performed to deliver ions 373 to the sidewalls of the first and second stacks 302, 303 of the upper portion 362. In various embodiments, the PLAD process may provide N and/or P type dopants to another S/D epitaxial layer 375, which is formed along the first layers 306 and the spacer 324 of the upper portion 362. As described above, the S/D epitaxial layer 375 may include a plurality of material formations 376 separated by gaps 377. In some embodiments, a thermal process may be performed after the second PLAD process to activate the dopants, as demonstrated by layer 380 in FIG. 3C.

Next, as further shown in FIG. 3C, a second metal 383 may be formed over the stacks 302, 303 of the upper portion 362, including within a trench 384 defined by the stacks 302, 303. The second metal 383 may be deposited directly atop the middle dielectric layer 370 and over the layer 380 of the S/D epitaxial layer 375. As shown, the second metal 383 may form a frontside contact 346, which extends through an opening of the ILD 372. Similarly, the metal 344 of the lower portion 360 may extend through the base layer 304 to form a backside contact 350. It will be appreciated that the metal or metal composition of the metal 344 may be the same or different from the second metal 383.

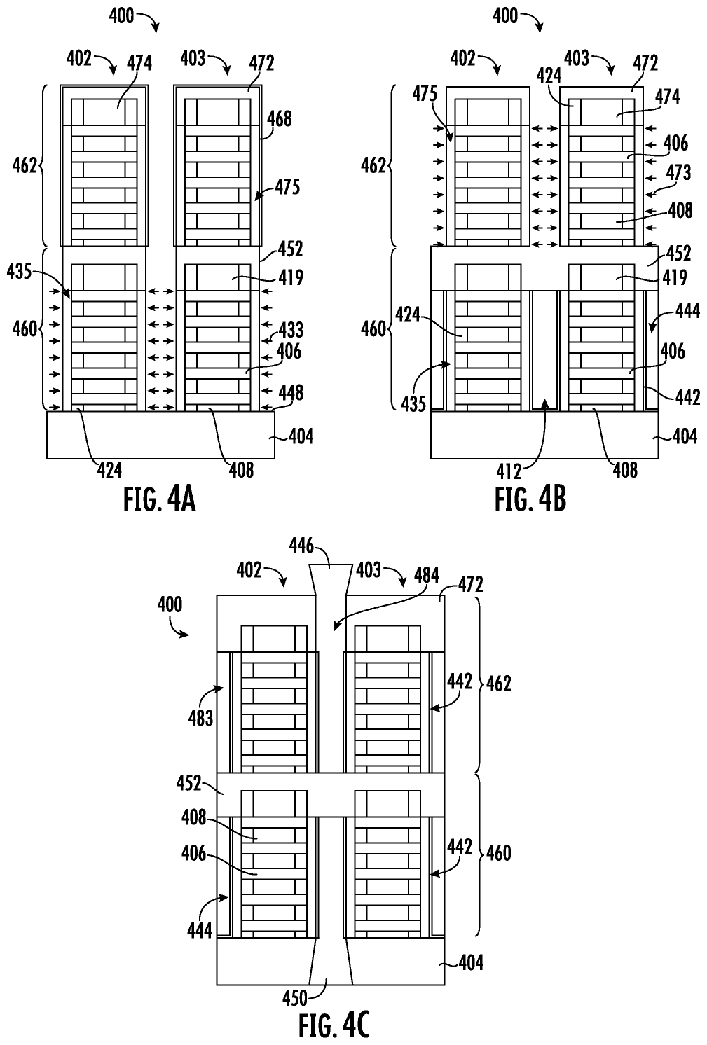

Referring now to FIGS. 4A-4C, another device according to embodiments of the present disclosure is shown. The device 400 may be the same or similar in many aspects to the device 300. As such, only certain aspects of the device 400 will hereinafter be described for the sake of brevity. As first shown in FIG. 4A, the device 400 may be a CFET having stacks 402, 403, each having a lower portion 460 separated from an upper portion 462 by a dielectric layer 452. The lower portion 460 and the upper portion 462 may each include alternating first layers 406 and second layers 408.

A PLAD process may be performed to deliver ions 433 to the sidewalls of the first and second stacks 402, 403, including into an S/D epitaxial layer 435, which is formed along the first layers 406 and a spacer 424 of the lower portion 460. As described above, the S/D epitaxial layer 435 may include a material layer extending continuously from an upper surface 448 of a base layer 404 to a gate 419 of the lower portion 460 of the stacks 402, 403. As shown, the dielectric layer 452 may wrap around gates 419, and extend to a top of the S/D epitaxial layer 435.

In this embodiment, another S/D epitaxial layer 475 may be formed along the first layers 406 and the spacer 424 of the upper portion 462. S/D epitaxial layer 475 may include a material layer extending continuously from an upper surface of the dielectric layer 452 to a gate 474 of the upper portion 462. A dielectric liner 468 may be formed over each of the first and second stacks 402, 403 of the upper portion 462, including over an ILD 472 atop the gate 474. In some embodiments, a thermal process may be performed after the PLAD process to activate the dopants of the S/D epitaxial layer 435 of the lower portion 460.

As shown in FIG. 4B, a metal 444 may then be formed over the lower portion 460 of the first stack 402 and the second stack 403, including within trench 412 and over layer 442 of the S/D epitaxial layer 435. After the dielectric liner 468 has been removed from the upper portion 462, another PLAD process may be performed to deliver ions 473 to the sidewalls of the S/D epitaxial layer 475. In some embodiments, a thermal process may be performed after the second PLAD process to activate the dopants of the S/D epitaxial layer 475.

Next, as further shown in FIG. 4C, a second metal 483 may be formed over the stacks 402, 403 of the upper portion 462, including within a trench 484 defined by the stacks 402, 403. The second metal 483 may be deposited directly atop the dielectric layer 452 and along layer 442. As shown, the second metal 483 may form a frontside contact 446, which extends through an opening of the ILD 472. Similarly, the metal 444 of the lower portion 460 may extend through the base layer 404 to form a backside contact 450.

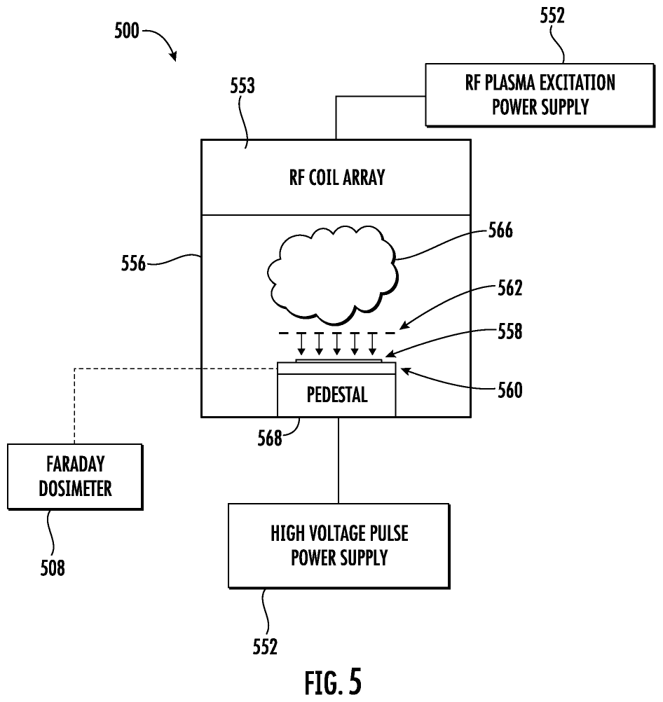

Referring to FIG. 5, an example system 500 (e.g., a PLAD system) operable to provide pulsed RF-excited continuous plasma doping to the devices 100, 200, 300, and 400 described herein. As shown, the system 500 may include a plasma power supply 503, a voltage pulse power supply 504, an RF coil array 506, and a dosimeter 508. Within a plasma chamber 510 is a wafer/substrate 502, which may be the same or similar to the substrate base described above. A platen/pedestal 514 may support the wafer 502, and a sheath 518 may be formed above the wafer 502. A temperature of the platen/pedestal 514 may be elevated (e.g., to 300° C. or greater) during plasma doping. In other embodiments, the platen/pedestal 514 may be maintained at room temperature during plasma doping. The dosimeter 508 may be a Faraday dosimeter or other type of sensor that directly measures the dose of ions received by the wafer 502. Although non-limiting, the dosimeter can be located on the pedestal 514, proximate to the wafer 502.

During use, the plasma power supply 503 and the RF coil array 506 deliver radio frequency excitation to generate a plasma 525 when gaseous species are delivered into the plasma chamber 510. For example, the plasma power supply 503 may be an RF powered inductively coupled power source to generate inductively coupled plasma 525, as known in the art. Gaseous species may be delivered from one or more gas sources (not separately shown) to generate ions of any suitable species, such as boron.

The voltage pulse power supply 504 may generate a bias voltage between the wafer 502 and the plasma chamber 510. As such, when the voltage pulse power supply 504 generates a voltage between the plasma chamber 510 and the substrate 502, a similar, but slightly larger, voltage difference is generated between the plasma 525 and the substrate 502. In one non-limiting example, a 5000 (5 kV) voltage difference established between the plasma chamber 510 and the substrate 502 (or, equivalently, pedestal 514) may generate a voltage difference of approximately 5005 V to 5030 V between the plasma 525 and the substrate 502.

In some embodiments, the voltage pulse power supply 504 may generate a bias voltage as a pulsed voltage signal, wherein the pulsed voltage signal is applied in a repetitive and regular manner, to generate a pulse routine comprising a plurality of extraction voltage pulses. For example, a pulse routine may apply voltage pulses of 500 V magnitude, 1000 V magnitude, 2000 V magnitude, 5000 V magnitude, or 10,000 V magnitude in various non-limiting embodiments. The system 500 may further include a controller (not shown), to control the pulsing routine applied to the substrate 502, in order to provide the sidewall doping.

According to various embodiments, the plasma 525 may be formed at least in part of ions that constitute an amorphizing species, wherein the amorphizing species may be any suitable ion capable of amorphizing an initially crystalline region of materials, such as the substrate 502. In various non-limiting embodiments, such suitable ions may include boron. When the plasma 525 is present in the plasma chamber 510, the controller may generate a signal for the voltage pulse power supply 504 to apply a pulse routine to the substrate 502, where the pulse routine constitutes a plurality of extraction voltage pulses. As such, when the extraction voltage pulses are applied between the substrate 502 and plasma 525, ions are extracted in pulsed form from the plasma 525, generating a plurality of ion pulses that are directed to the substrate 502.

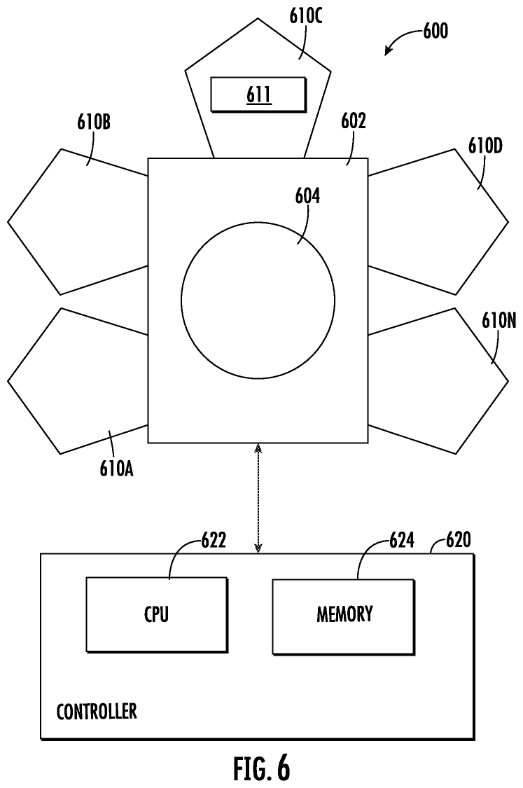

FIG. 6 shows a schematic of another example apparatus/system 600 according to embodiments of the disclosure. In some embodiments, the system 600 may be a cluster tool operable to perform processes necessary to form the devices 100, 200, 300, and 400 described herein. Although non-limiting, the system 600 may include at least one central transfer station/chamber 602 and one or more robots 604 within the transfer station/chamber 602, wherein the robot 604 is operable to move a robot blade and a wafer to and from each of a plurality of processing chambers 610A-610N connected with, or positioned adjacent to, the transfer station/chamber 602. In some embodiments, the processing chambers 610A-610N may support angled beamline ion implantation, material deposition, and material etching. The particular arrangement of process chambers and components can be varied depending on the cluster tool, and should not be taken as limiting the scope of the disclosure. In another example, one or more of the chambers may include multiple process regions within a same chamber, which permits a common supply of gases, common pressure control, and common process gas exhaust/pumping. Modular design of the system enables rapid conversion from one configuration to any other.

In some embodiments, processing chamber 610A may be a deposition chamber, processing chamber 610B may be an etch chamber, and processing chamber 610C may house an ion processing tool 611 operable to perform the implant process in which ions are directed into the stacks of layers, as described herein. In some embodiments, the ion processing tool 611 may be a PLAD tool. In some embodiments, processing chamber 610D may be operable to perform one or more thermal processes,

A system controller 620 is in communication with the robot 604, the transfer station/chamber 602, and the plurality of processing chambers 610A-610N. The system controller 620 can be any suitable component that can control the processing chambers 610A-610N and robot(s) 604, as well as the processes occurring within the process chambers 610A-610N. For example, the system controller 620 can be a computer including a central processing unit 622, memory 624, suitable circuits/logic/instructions, and storage.

Processes or instructions may generally be stored in the memory 624 of the system controller 620 as a software routine that, when executed by the processor 622, causes the processing chambers 610A-610N to perform processes of the present disclosure. The software routine may also be stored and/or executed by a second processor (not shown) that is remotely located from the hardware being controlled by the processor 622. Some or all of the method(s) of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor 622, transforms the general-purpose computer into a specific purpose computer (controller) that controls the chamber operation such that the processes are performed.

In various embodiments, design tools can be provided and configured to create the datasets used to pattern the semiconductor layers of the device, e.g., as described herein. For example, data sets can be created to generate photomasks used during lithography operations to pattern the layers for structures as described herein. Such design tools can include a collection of one or more modules and can also be comprised of hardware, software or a combination thereof. Thus, for example, a tool can be a collection of one or more software modules, hardware modules, software/hardware modules or any combination or permutation thereof. As another example, a tool can be a computing device or other appliance running software, or implemented in hardware.

For the sake of convenience and clarity, terms such as “top,” “bottom,” “upper,” “lower,” “vertical,” “horizontal,” “lateral,” and “longitudinal” will be used herein to describe the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporate the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, the present disclosure has been described herein in the context of a particular implementation in a particular environment for a particular purpose. Those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A method, comprising:
forming a plurality of layered stacks atop a base layer, wherein a first layered stack and a second layered stack of the plurality of layered stacks each comprises a plurality of alternating first layers and second layers, and wherein the first layered stack and the second layered stack of the plurality of layered stacks define a trench;
forming a source/drain epitaxial layer along a sidewall of the first layered stack and the second layered stack;
performing an implant by directing ions to the source/drain epitaxial layer, wherein the implant increases an ion concentration along an outer surface of the source/drain epitaxial layer; and
performing a thermal process on the plurality of layered stacks and the source/drain epitaxial layer after performing the implant.

2. The method of claim 1, further comprising depositing a metal over the plurality of layered stacks, including within the trench, to form a contact.

3. The method of claim 1, wherein the source/drain epitaxial layer along the sidewall of the first layered stack and the second layered stack comprises a plurality of alternating material formations and gaps.

4. The method of claim 1, wherein the source/drain epitaxial layer along the sidewall of the first layered stack and the second layered stack comprises a continuous material layer extending from an upper surface of the base layer to a gate of the first layered stack and the second layered stack.

5. The method of claim 1, wherein performing the thermal process comprises performing an anneal immediately after the implant is performed.

6. The method of claim 1, wherein performing the implant comprises performing a plasma doping process.

7. The method of claim 1, wherein forming the plurality of layered stacks atop the base layer comprises:
forming a lower portion of the plurality of alternating first layers and second layers, wherein the implant is performed on the source/drain epitaxial layer formed along the lower portion of the plurality of alternating first layers and second layers;
forming a middle dielectric layer atop the lower portion after the implant is performed on the lower portion;
forming, atop the middle dielectric layer, an upper portion of the plurality of alternating first layers and second layers; and
performing a second implant by directing ions to a second source/drain epitaxial layer formed along the upper portion of the plurality of alternating first layers and second layers.

8. The method of claim 7, further comprising:
forming a metal over the lower portion of the plurality of alternating first layers and second layers to form a backside contact though the base layer; and
forming a metal over the upper portion of the plurality of alternating first layers and second layers to form a frontside contact.

9. A method for forming a gate-all-around (GAA) device, comprising:
forming a plurality of nanosheet (NS) stacks atop a substrate, wherein a first NS stack and a second NS stack of the plurality of NS stacks each comprises a plurality of alternating first layers and second layers, and wherein the first NS stack and the second NS stack of the plurality of layered stacks define a trench extending to an upper surface of the substrate;
forming a source/drain epitaxial layer along a sidewall of the first NS stack and the second NS stack;
performing an implant by directing ions to the source/drain epitaxial layer, wherein the implant increases an ion concentration along an outer surface of the source/drain epitaxial layer; and
performing a thermal process on the plurality of NS stacks and the source/drain epitaxial layer after performing the implant.

10. The method of claim 9, further comprising depositing a metal over the plurality of NS stacks, including within the trench, to form a contact.

11. The method of claim 9, wherein the source/drain epitaxial layer along the sidewall of the first NS stack and the second NS stack comprises one of: a plurality of alternating material formations and gaps, and a continuous material layer extending from an upper surface of the base layer to a gate of the first NS stack and the second NS stack.

12. The method of claim 9, wherein performing the thermal process comprises performing an anneal immediately after the implant is performed.

13. The method of claim 9, wherein performing the implant comprises performing a plasma doping process.

14. The method of claim 9, wherein forming the plurality of NS stacks atop the base layer comprises:
forming a lower portion of the plurality of alternating first layers and second layers, wherein the implant is performed on the source/drain epitaxial layer formed along the lower portion of the plurality of alternating first layers and second layers;
forming a middle dielectric layer atop the lower portion after the implant is performed on the lower portion;
forming, atop the middle dielectric layer, an upper portion of the plurality of alternating first layers and second layers; and
performing a second implant by directing ions to a second source/drain epitaxial layer formed along the upper portion of the plurality of alternating first layers and second layers.

15. The method of claim 14, further comprising:
forming a metal over the lower portion of the plurality of alternating first layers and second layers to form a backside contact though the base layer; and
forming the metal over the upper portion of the plurality of alternating first layers and second layers to form a frontside contact.

16. An ion processing tool operable to:
direct ions to a source/drain epitaxial layer formed along a sidewall of a first nanosheet stack and a second nanosheet stack of a plurality of nanosheet stacks, wherein the implant increases an ion concentration at an intersection of an outer surface of the source/drain epitaxial layer and a metal sidewall contact, and wherein each of the first and second nanosheet stacks comprises a plurality of alternating first layers and second layers formed atop a base layer.

17. The system of claim 16, wherein the ion processing tool is a plasma doping tool operable to perform a plasma doping process.

18. The system of claim 16, wherein the source/drain epitaxial layer along the sidewall of the first nanosheet stack and the second nanosheet stack comprises one of: a plurality of alternating material formations and gaps, and a continuous material layer extending from an upper surface of the base layer to a gate of the first nanosheet stack and the second nanosheet stack.
